(19) United States
(12) Patent Application Publication
(10) Pub. No.: US 2026/0349351 A1
(43) Pub. Date: Nov. 5, 2026

(54) METHOD OF DETERMINING FIDUCIAL DEGRADATION ON A LITHOGRAPHIC APPARATUS

(71) Applicant: ASML NETHERLANDS B.V., Veldhoven (NL)

(72) Inventors: Arvind RAVICHANDRAN, Eindhoven (NL); Hamze ISSA, Eindhoven (NL); Hamideh ROSTAMI, Weert (NL); Lucas DESARD, Ghent (BE)

(73) Assignee: ASML NETHERLANDS B.V., Veldhoven (NL)

(21) Appl. No.: 19/488,935

(22) PCT Filed: May 15, 2024
(86) PCT No.: PCT/EP2024/063356

§ 371 Date: Dec. 1, 2025

(30) Foreign Application Priority Data
Jun. 15, 2023 (EP) 23179421.5

(51) Int. Cl. G03F 7/00; G01B 11/26; G01M 11/02

(52) U.S. Cl. CPC G03F 7/70508; G01B 11/26; G01M 11/0242; G03F 7/70516; G03F 7/706; G03F 7/7085

(57) ABSTRACT

A method of determining fiducial degradation on a lithographic apparatus, the method including: obtaining first fiducial metrology data from a measurement side of the lithographic apparatus; obtaining second fiducial metrology data from an exposure side of the lithographic apparatus; determining a correlation metric describing a correlation between the first fiducial metrology data and the second fiducial metrology data; and determining whether a fiducial has degraded from the correlation metric.

### CROSS-REFERENCE TO RELATED APPLICATIONS

This application claims priority of EP application 23179421.5 which was filed on Jun. 15, 2023 and which is incorporated herein in its entirety by reference.

### FIELD

The present invention relates to methods and apparatus usable, for example, in the manufacture of devices by lithographic techniques, and to methods of manufacturing devices using lithographic techniques.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. including part of a die, one die, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. These target portions are commonly referred to as “fields”.

In the manufacture of complex devices, typically many lithographic patterning steps are performed, thereby forming functional features in successive layers on the substrate. A critical aspect of performance of the lithographic apparatus is therefore the ability to place the applied pattern correctly and accurately in relation to features laid down (by the same apparatus or a different lithographic apparatus) in previous layers. For this purpose, the substrate is provided with one or more sets of alignment marks. Each mark is a structure whose position can be measured at a later time using a position sensor, typically an optical position sensor. The lithographic apparatus includes one or more alignment sensors by which positions of marks on a substrate can be measured accurately. Different types of marks and different types of alignment sensors are known from different manufacturers and different products of the same manufacturer.

In other applications, metrology sensors are used for measuring exposed structures on a substrate (either in resist and/or after etch). A fast and non-invasive form of specialized inspection tool is a scatterometer in which a beam of radiation is directed onto a target on the surface of the substrate and properties of the scattered or reflected beam are measured. Examples of known scatterometers include angle-resolved scatterometers of the type described in US2006033921A1 and US2010201963A1. In addition to measurement of feature shapes by reconstruction, diffraction based overlay can be measured using such apparatus, as described in published patent application US2006066855A1. Diffraction-based overlay metrology using dark-field imaging of the diffraction orders enables overlay measurements on smaller targets. Examples of dark field imaging metrology can be found in international patent applications WO 2009/078708 and WO 2009/106279 which documents are hereby incorporated by reference in their entirety. Further developments of the technique have been described in published patent publications US20110027704A, US20110043791A, US2011102753A1, US20120044470A, US20120123581A, US20130258310A, US20130271740A and WO2013178422A1. These targets can be smaller than the illumination spot and may be surrounded by product structures on a wafer. Multiple gratings can be measured in one image, using a composite grating target. The contents of all these applications are also incorporated herein by reference.

A known lithographic apparatus or “scanner” may comprise a measurement side and an exposure side. At the measurement side, the position of marks on the wafer may be measured relative to a common reference or fiducial. At the expose side, the position and shape of the reticle is measured relative to the fiducial. In this manner, a common reference frame between measure side and expose side is established. Thus reference frame may be used to align the measure side wafer measurements to the required expose side exposure actuations.

The methods and/or locations for performing measurements on the fiducial respectively at the measure side and exposure side are different. Because of this difference, some errors (e.g., resultant from degradation of the fiducial) are only seen by the measure side and not by exposure side and vice versa. Examples of errors seen only by the measure side, are those due to degradation of the protective layer on the sensor or plate mark degradation). As the exposure side uses the measurement side measurements as reference, it cannot correct for these errors, which it is unable to measure, and as such these errors will be seen in the exposure on the wafer.

### SUMMARY OF THE INVENTION

The invention in a first aspect provides a method of determining fiducial degradation on a lithographic apparatus, the method comprising: obtaining first fiducial metrology data from a measurement side of the lithographic apparatus; obtaining second fiducial metrology data from an exposure side of the lithographic apparatus; determining a correlation metric describing a correlation between said first fiducial metrology data and said second fiducial metrology data; and determining whether a fiducial has degraded from said correlation metric.

The invention in a second aspect provides a method of determining fiducial degradation on a lithographic apparatus, the method comprising: obtaining a first set of second fiducial metrology data relating to a first substrate support of the lithographic apparatus, said second fiducial metrology data being obtained from an exposure side of the lithographic apparatus; obtaining a second set of second fiducial metrology data relating to a second substrate support of the lithographic apparatus; determining a difference of said first set of second fiducial metrology data and said second set of second fiducial metrology data; and determining whether a fiducial has degraded on either one or both of said first substrate support and/or second substrate support from said difference.

Also disclosed is a computer program and lithographic apparatus being operable to perform the method of the first aspect or second aspect.

The above and other aspects of the invention will be understood from a consideration of the examples described below.

### BRIEF DESCRIPTION OF THE DRAWINGS

Embodiments of the invention will now be described, by way of example only, with reference to the accompanying drawings, in which:

FIG. 1 depicts a lithographic apparatus;

FIG. 2 illustrates schematically measurement and exposure processes in the apparatus of FIG. 1;

FIG. 3 is a flowchart describing a method of determining fiducial degradation according to a first embodiment; and

FIG. 4 is a flowchart describing a method of determining on-product impact of fiducial degradation according to a second embodiment.

### DETAILED DESCRIPTION

Before describing embodiments of the invention in detail, it is instructive to present an example environment in which embodiments of the present invention may be implemented.

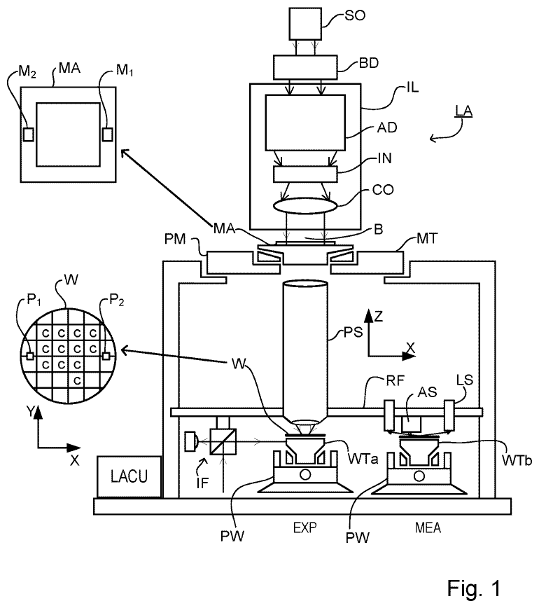

FIG. 1 schematically depicts a lithographic apparatus LA. The apparatus includes an illumination system (illuminator) IL configured to condition a radiation beam B (e.g., UV radiation or DUV radiation), a patterning device support or support structure (e.g., a mask table) MT constructed to support a patterning device (e.g., a mask) MA and connected to a first positioner PM configured to accurately position the patterning device in accordance with certain parameters; two substrate tables (e.g., a wafer table) WTa and WTb each constructed to hold a substrate (e.g., a resist coated wafer) W and each connected to a second positioner PW configured to accurately position the substrate in accordance with certain parameters; and a projection system (e.g., a refractive projection lens system) PS configured to project a pattern imparted to the radiation beam B by patterning device MA onto a target portion C (e.g., including one or more dies) of the substrate W. A reference frame RF connects the various components, and serves as a reference for setting and measuring positions of the patterning device and substrate and of features on them.

The illumination system may include various types of optical components, such as refractive, reflective, magnetic, electromagnetic, electrostatic or other types of optical components, or any combination thereof, for directing, shaping, or controlling radiation.

The patterning device support MT holds the patterning device in a manner that depends on the orientation of the patterning device, the design of the lithographic apparatus, and other conditions, such as for example whether or not the patterning device is held in a vacuum environment. The patterning device support can use mechanical, vacuum, electrostatic or other clamping techniques to hold the patterning device. The patterning device support MT may be a frame or a table, for example, which may be fixed or movable as required. The patterning device support may ensure that the patterning device is at a desired position, for example with respect to the projection system.

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

As here depicted, the apparatus is of a transmissive type (e.g., employing a transmissive patterning device). Alternatively, the apparatus may be of a reflective type (e.g., employing a programmable mirror array of a type as referred to above, or employing a reflective mask). Examples of patterning devices include masks, programmable mirror arrays, and programmable LCD panels. Any use of the terms “reticle” or “mask” herein may be considered synonymous with the more general term “patterning device.” The term “patterning device” can also be interpreted as referring to a device storing in digital form pattern information for use in controlling such a programmable patterning device.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems.

In operation, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may for example include an adjuster AD for adjusting the angular intensity distribution of the radiation beam, an integrator IN and a condenser CO. The illuminator may be used to condition the radiation beam, to have a desired uniformity and intensity distribution in its cross section.

The radiation beam B is incident on the patterning device MA, which is held on the patterning device support MT, and is patterned by the patterning device. Having traversed the patterning device (e.g., mask) MA, the radiation beam B passes through the projection system PS, which focuses the beam onto a target portion C of the substrate W. With the aid of the second positioner PW and position sensor IF (e.g., an interferometric device, linear encoder, 2-D encoder or capacitive sensor), the substrate table Wta or WTb can be moved accurately, e.g., so as to position different target portions C in the path of the radiation beam B. Similarly, the first positioner PM and another position sensor (which is not explicitly depicted in FIG. 1) can be used to accurately position the patterning device (e.g., mask) MA with respect to the path of the radiation beam B, e.g., after mechanical retrieval from a mask library, or during a scan.

Patterning device (e.g., mask) MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the mask alignment marks may be located between the dies. Small alignment marks may also be included within dies, in amongst the device features, in which case it is desirable that the markers be as small as possible and not require any different imaging or process conditions than adjacent features. The alignment system, which detects the alignment markers is described further below.

The depicted apparatus could be used in a variety of modes. In a scan mode, the patterning device support (e.g., mask table) MT and the substrate table WT are scanned synchronously while a pattern imparted to the radiation beam is projected onto a target portion C (i.e., a single dynamic exposure). The speed and direction of the substrate table WT relative to the patterning device support (e.g., mask table) MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. Other types of lithographic apparatus and modes of operation are possible, as is well-known in the art. For example, a step mode is known. In so-called “maskless” lithography, a programmable patterning device is held stationary but with a changing pattern, and the substrate table WT is moved or scanned.

Combinations and/or variations on the above described modes of use or entirely different modes of use may also be employed.

Lithographic apparatus LA is of a so-called dual stage type which has two substrate tables Wta, WTb and two stations-an exposure station EXP and a measurement station MEA-between which the substrate tables can be exchanged. While one substrate on one substrate table is being exposed at the exposure station, another substrate can be loaded onto the other substrate table at the measurement station and various preparatory steps carried out. This enables a substantial increase in the throughput of the apparatus. The preparatory steps may include mapping the surface height contours of the substrate using a level sensor LS and measuring the position of alignment markers on the substrate using an alignment sensor AS. If the position sensor IF is not capable of measuring the position of the substrate table while it is at the measurement station as well as at the exposure station, a second position sensor may be provided to enable the positions of the substrate table to be tracked at both stations, relative to reference frame RF. Other arrangements are known and usable instead of the dual-stage arrangement shown. For example, other lithographic apparatuses are known in which a substrate table and a measurement table are provided. These are docked together when performing preparatory measurements, and then undocked while the substrate table undergoes exposure.

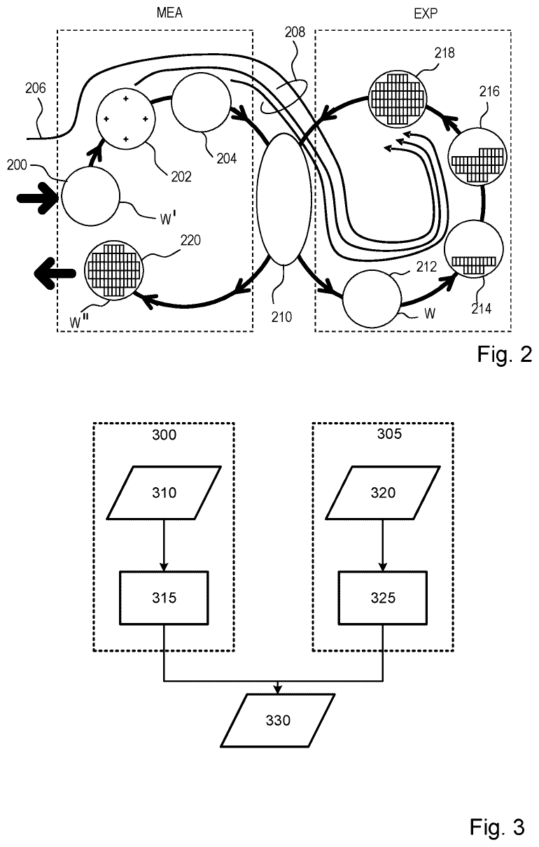

FIG. 2 illustrates the steps to expose target portions (e.g. dies) on a substrate W in the dual stage apparatus of FIG. 1. On the left hand side within a dotted box are steps performed at a measurement station MEA, while the right hand side shows steps performed at the exposure station EXP. From time to time, one of the substrate tables Wta, WTb will be at the exposure station, while the other is at the measurement station, as described above. For the purposes of this description, it is assumed that a substrate W has already been loaded into the exposure station. At step 200, a new substrate W′ is loaded to the apparatus by a mechanism not shown. These two substrates are processed in parallel in order to increase the throughput of the lithographic apparatus.

Referring initially to the newly-loaded substrate W′, this may be a previously unprocessed substrate, prepared with a new photo resist for first time exposure in the apparatus. In general, however, the lithography process described will be merely one step in a series of exposure and processing steps, so that substrate W′ has been through this apparatus and/or other lithography apparatuses, several times already, and may have subsequent processes to undergo as well. Particularly for the problem of improving overlay performance, the task is to ensure that new patterns are applied in exactly the correct position on a substrate that has already been subjected to one or more cycles of patterning and processing. These processing steps progressively introduce distortions in the substrate that must be measured and corrected for, to achieve satisfactory overlay performance.

The previous and/or subsequent patterning step may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

At 202, alignment measurements using the substrate marks P1 etc. and image sensors (not shown) are used to measure and record alignment of the substrate relative to substrate table Wta/WTb. In addition, several alignment marks across the substrate W′ will be measured using alignment sensor AS. These measurements are used in one embodiment to establish a “wafer grid”, which maps very accurately the distribution of marks across the substrate, including any distortion relative to a nominal rectangular grid.

At step 204, a map of wafer height (Z) against X-Y position is measured also using the level sensor LS. Conventionally, the height map is used only to achieve accurate focusing of the exposed pattern. It may be used for other purposes in addition.

When substrate W′ was loaded, recipe data 206 were received, defining the exposures to be performed, and also properties of the wafer and the patterns previously made and to be made upon it. To these recipe data are added the measurements of wafer position, wafer grid and height map that were made at 202, 204, so that a complete set of recipe and measurement data 208 can be passed to the exposure station EXP. The measurements of alignment data for example comprise X and Y positions of alignment targets formed in a fixed or nominally fixed relationship to the product patterns that are the product of the lithographic process. These alignment data, taken just before exposure, are used to generate an alignment model with parameters that fit the model to the data. These parameters and the alignment model will be used during the exposure operation to correct positions of patterns applied in the current lithographic step. The model in use interpolates positional deviations between the measured positions. A conventional alignment model might comprise four, five or six parameters, together defining translation, rotation and scaling of the ‘ideal’ grid, in different dimensions. Advanced models are known that use more parameters.

At 210, wafers W′ and W are swapped, so that the measured substrate W′ becomes the substrate W entering the exposure station EXP. In the example apparatus of FIG. 1, this swapping is performed by exchanging the supports Wta and WTb within the apparatus, so that the substrates W, W′ remain accurately clamped and positioned on those supports, to preserve relative alignment between the substrate tables and substrates themselves. Accordingly, once the tables have been swapped, determining the relative position between projection system PS and substrate table WTb (formerly Wta) is all that is necessary to make use of the measurement information 202, 204 for the substrate W (formerly W′) in control of the exposure steps. At step 212, reticle alignment is performed using the mask alignment marks M1, M2. In steps 214, 216, 218, scanning motions and radiation pulses are applied at successive target locations across the substrate W, in order to complete the exposure of a number of patterns.

By using the alignment data and height map obtained at the measuring station in the performance of the exposure steps, these patterns are accurately aligned with respect to the desired locations, and, in particular, with respect to features previously laid down on the same substrate. The exposed substrate, now labeled W″ is unloaded from the apparatus at step 220, to undergo etching or other processes, in accordance with the exposed pattern.

The skilled person will know that the above description is a simplified overview of a number of very detailed steps involved in one example of a real manufacturing situation. For example rather than measuring alignment in a single pass, often there will be separate phases of coarse and fine measurement, using the same or different marks. The coarse and/or fine alignment measurement steps can be performed before or after the height measurement, or interleaved.

In the flow of FIG. 2, on the measurement side, the wafer alignment data measured at step 202 and the wafer height/leveling data measured at step 204 are both measured with respect to a reference arrangement or fiducial. For example, the fiducial may comprise a fiducial sensor on a wafer stage or chuck (more generally a substrate support) and a plurality of reference structures (e.g., a set of marks), comprising respectively one or more reference structures or marks on the substrate support and one or more reference structures or marks on the reticle and/or reticle stage.

On the measurement side, an alignment sensor and/or leveling sensor illuminates the one or more substrate support marks on the fiducial surface during alignment and leveling (typically both will be performed; however the concepts disclosed herein are individually applicable to measurement-to-exposure matching in one or both dimensions parallel to the substrate plane and/or the direction perpendicular to the substrate plane). As a result, the aligned wafer position in the wafer plane is described with respect to the fiducial by the wafer alignment data (measurements of alignment structures or marks on the wafer) and/or the wafer position in the direction perpendicular to the wafer plane is described with respect to the fiducial by the leveling data. Typically more than one mark is measured on the fiducial, enabling the shape, and therefore any drift in this shape over time, of the fiducial surface to be characterized or modeled. This may be done using alignment modeling techniques, e.g., to measure and model an aligned position deviation (APD) with respect to nominal or expected positions of each mark assuming a perfectly flat surface.

On the exposure side, the reticle alignment step of step 212 aligns the reticle with respect to the fiducial. This may be achieved by using the fiducial sensor on the fiducial to measure illumination (e.g., from the exposure source) via one or more reference structures or marks on the reticle and/or reticle stage. In addition to reticle stage positioning, other corrections may be performed at the expose side, e.g., lens corrections based on lens aberration measurements (wavefront measurements) which may also be performed by the fiducial sensor.

In performing these measurement steps 202, 204, 212, each with respect to the fiducial, the position of the reticle with respect to the wafer can be determined.

The exposure side metrology uses the measurement side metrology as a baseline and assumes that the measurements are correct. For example, the exposure side will correct exposure side measurements and/or models (e.g., for reticle shape and/or lens aberrations) based on the fiducial surface shape measured on the measurement side.

An initial calibration step, sometimes referred to as measurement-to-exposure matching, is typically performed during set-up of the lithographic apparatus. Simplistically, this matching is done using “stage alignment” measurements in measurement side, and “reticle alignment” measurements on the exposure side. This matching calibrates any difference between the exposure side fiducial metrology to the measurement side fiducial metrology due to the different methods used at each side. During production, the fiducial is subject to temporal drift. As such, the measurement side metrology is performed routinely on the fiducial to characterize/model this drift. In this manner, any changes to the fiducial over time will be taken into account at the exposure side. However, monitoring of this drift works under the assumption that the measured fiducial will be seen the same on the measurement side and exposure side, such that the same fiducial temporal drift is captured.

However, because the measurement methods and measured structures on each side differ this is not always the case, and differences in the measured drift will be detected on each side in practice. In particular, because only the measurement side measures (marks on) the surface of the fiducial, rather than using cameras/detectors within the fiducial, anything which degrades this surface and/or the marks thereon will be detected only on the measurement side. Such degradation includes degradation of the marks themselves and/or of the fiducial coating.

Once the measurement side metrology is modeled, the modeled data will comprise a main fiducial description component describing the fiducial surface shape and an additional nuisance component resulting from the fiducial degradation. On the expose side, this additional nuisance component will not be measured, only the main component. The expose side control will therefore incorrectly assume that this additional nuisance component has resulted from expose side error (e.g., reticle, lens and/or reticle stage error) and determine erroneous corrections for this (e.g., via reticle, lens and/or reticle stage control/actuation). These erroneous “corrections” will be directly responsible for imaging errors in the final product.

Fiducial plate degradation, and its effect on on-product performance is a primary cause for fiducial swaps in lithographic apparatuses.

To address this issue, a method for detecting the presence of this fiducial degradation measurable only by the measurement side (e.g., resulting from changes over time in the fiducial surface measured on the measurement side) is proposed. In another embodiment, a method for quantifying the on-product effect of this fiducial degradation is also proposed.

For example, it is proposed that a correlation metric is determined which describes a degree of correlation between measurement side metrology data and exposure side metrology data. This correlation metric may be used to identify onset of fiducial surface/mark degradation; e.g., specifically once correlation reaches a threshold indicative of high correlation then it can be assumed that fiducial surface/mark degradation is present and having an effect on the on-product performance. This can be understood intuitively in that the measurement side fiducial metrology and exposure side fiducial metrology are typically measuring very different, unrelated parameters (e.g., fiducial surface shape vs. lens aberrations) which would not be expected to correlate. Any sufficiently strong correlation therefore is likely to have a common cause, and this common cause will be from the measurement side fiducial metrology.

As such, a method is disclosed comprising obtaining at least first fiducial metrology data being obtained from a measurement side of a lithographic apparatus and second fiducial metrology data being obtained from an exposure side of the lithographic apparatus; determining a correlation metric describing a correlation between said first fiducial metrology data and said second fiducial metrology data; and determining whether a fiducial has degraded from said correlation metric.

FIG. 3 is a flowchart describing such a first method for detecting the onset of fiducial degradation measurable only by the measurement side. A lithographic apparatus comprises a measurement side 300 and an exposure side 305. Fiducial metrology performed on the measurement side 300 yields first fiducial metrology data 310. This first fiducial metrology data 310 may comprise position measurements or APD measurements of one or marks on the fiducial surface and/or leveling data. This first fiducial metrology data 310 may be modeled 315 to obtain a model description of the fiducial surface (first model). In a specific non-limiting example, the model parameters may comprise translation, rotation, magnification, and optionally higher order terms. Fiducial metrology performed on the exposure side 305 yields second fiducial metrology data 320. By way of example, this second fiducial measurement data may comprise corresponding lens aberration data/wavefront data (e.g., in the form of Zernike coefficients). This second fiducial metrology data 320 may be modeled 325 to obtain a model description of the exposure lens aberrations (second model). At step 330, a correlation metric may be determined describing the correlation between the first fiducial metrology data 310 and second fiducial metrology data 320. This correlation metric may determine correlation from the raw data 310, 320 or the modeled data subsequent to steps 315, 325. Based on the correlation metric (e.g., by comparing to a threshold value), a time at which the fiducial surface or marks thereon begin to degrade to an unacceptable level can be identified; this may be when correlation is high. Based on this a maintenance action (e.g., a fiducial replacement) may be performed.

The correlation metric in an embodiment may be determined by filtering exposure side (e.g., Lot Correction) parameters using e.g., a Median filter. A median filter is a well-known order-statistic filter due to its good performance for some specific noise types such as “Gaussian,” “random,” and “salt and pepper” noises. With a median filter, the center pixel of a M x M neighborhood is replaced by the median value of the corresponding window. This filter may be used to remove noise from exposure side parameters.

The correlation metric in an embodiment may be determined by calculating the spearman correlation between (e.g., filtered or cleaned) first fiducial metrology data (e.g., as modeled; i.e., exposure side or first model parameters) and corresponding second fiducial metrology data (e.g., as modeled; i.e., measurement side or second model parameters) in a windowing approach. By way of specific example, a window of e.g., 15 days may be defined, with the window being slid for one day after each correlation calculation. Spearman correlation has the range of −1 to +1 where −1 indicates high negative correlation and +1 high positive correlation.

After identifying the moment in time where the fiducial starts degrading, it is proposed in an embodiment to quantify a common rate of drift between the exposure side and measurement side parameters. Using this common rate of drift, it is possible to make a reasonable estimation of how much of the drift in the exposure side measurements is due to the plate degradation, e.g., by using linear regression and correlation techniques. This is possible due to the fact that in most cases, once the fiducial starts degrading, this will be the major contributor to the drift and therefore it may be assumed that the fiducial degradation is the sole cause of this common drift. Once quantified, an equivalent correction may be provided to the measurement side metrology in subsequent modeling, such that the fiducial degradation issue can be mitigated. However, a preferred method for determining a corrections will be described in the context of a second embodiment.

A second embodiment for addressing the same fiducial degradation issue may use a chuck-to-chuck difference of exposure side metrology data (second fiducial metrology data) as a metric for determining when the fiducial starts degrading. This embodiment may also enable the on-product impact of the fiducial degradation (e.g., in terms of overlay) to be determined. The chuck-to-chuck difference may comprise the difference between the (e.g., modeled) exposure-side measurements (e.g., wavefront sensor/Zernike measurements) between the two chucks (substrate supports) of the lithographic apparatus. As has been described in relation to FIG. 2, the swapping between measurement side and exposure side is performed by exchanging the chucks or substrate supports within the apparatus, such that a wafer remains clamped to a single support on both sides of the apparatus. Also, in the case of exposure side calibration measurements (e.g. lot correction), the same exposure elements (e.g. light source, reticle, lens) are used to perform the calibration. Therefore it can be assumed that any chuck-to-chuck difference can only originate from the measurement side and equates to a degradation contribution from fiducial degradation (e.g., degradation of the surface and/or mark on each chuck). This is especially the case where there are no issues with the sensing detectors in the fiducial used by the expose side.

As such, a method is disclosed which comprises obtaining at least a first set of second fiducial metrology data relating to a first substrate support of a lithographic apparatus and a second set of second fiducial metrology data relating to a second substrate support of the lithographic apparatus, said second fiducial metrology data being obtained from an exposure side of the lithographic apparatus; determining a difference of said first set of second fiducial metrology data and said second set of second fiducial metrology data; and determining whether a fiducial has degraded on either one or both of said first substrate support and second substrate support from said difference.

The method may further comprise a step of obtaining first fiducial metrology data from a measurement side of the lithographic apparatus, and determining one or both of an on-product impact of fiducial degradation and/or corrected first fiducial metrology data, corrected for the impact of said fiducial degradation, from said first fiducial metrology data and said difference. The method may determine said on-product impact of fiducial degradation and/or corrected first fiducial metrology data based on an inverse model of the model used to model said first fiducial metrology data. The method may determine said on-product impact of fiducial degradation and/or corrected first fiducial metrology data for the effect of a subset of measurement structures or marks on said fiducial, the subset being determined based on a measurement structure quality metric or mark quality metric for each of said measurement structures.

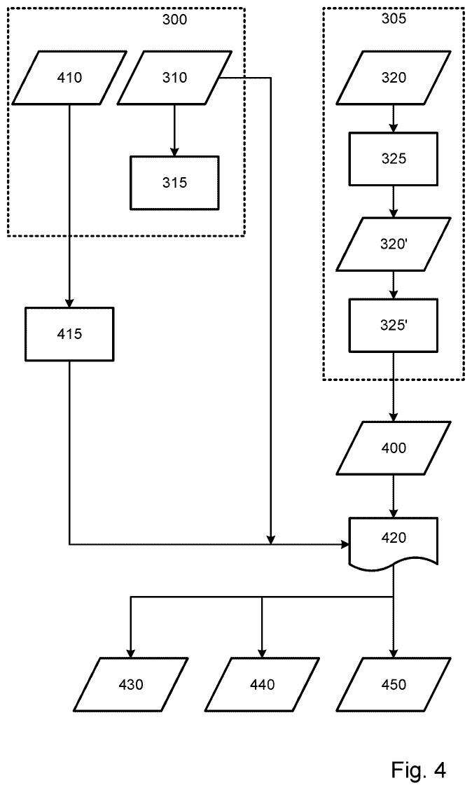

FIG. 4 is a flowchart describing such an embodiment. As before, on the expose side 305, second fiducial metrology data 320 may be modeled 325 to obtain a model description of the exposure lens aberrations. This is repeated 320′, 325′ for the other chuck, following which the chuck-to-chuck difference 400 between the modeled data at steps 325 and 325′ is determined. In one embodiment, this chuck-to-chuck difference 400 may be used simply to determine the presence of significant fiducial degradation, e.g., by comparing it to a threshold (e.g., should the chuck-to-chuck difference 400 become so large as to pass the threshold, then fiducial degradation may be assumed). This may trigger a maintenance action, for example.

However, the method may also comprise determining the on-product impact of the degradation. An advantage of this is that any exposure side corrections performed based on the exposure side metrology may account for this determined on-product impact. Presently, any degradation which is only seen by the measurement side will result in erroneous “correction” for the effect of this degradation. In an embodiment, determining on-product impact of this degradation enables it to be isolated from other (real) exposure side error contributors, such that any correction can be determined so as not to correct for the fiducial degradation contribution. This can be achieved, for example, in lot corrections based on wavefront/aberration metrology.

Referring again to FIG. 4, the on-product impact (e.g., overlay impact) 440 may be determined 420 from the chuck-to-chuck difference 400 and first fiducial metrology data 310 (e.g., the raw position data of the fiducial marks, rather than the modeled data 315). This may be achieved using an inverse fiducial surface model. To obtain a description of the fiducial surface, a fiducial surface model may be used to model 315 the first fiducial metrology data 310. However, in the presence of fiducial surface or mark degradation, the modeled data at step 315 will comprise the (true) shape contribution and a nuisance contribution from the degradation. Step 420 can use an inverse of this model to isolate the nuisance contribution 430 and its impact 440 in terms of on-product overlay from the true mark measurement data 450 (i.e., corrected first fiducial metrology data having been corrected for the nuisance contribution 430), based on the assumption that this nuisance contribution 430 is the sole contributor to the chuck-to-chuck difference 400. The expose side metrology may then use the modeled true mark measurement data 450 to describe the fiducial surface in determining exposure corrections. Note that this on-product impact 440 may be determined individually per chuck.

Typically, the first fiducial metrology data 310 may comprise measurement for a number of marks, for example four marks (e.g., the fiducial comprises at least four marks for shape determination and modeling). However, in some embodiments, the second fiducial metrology data 320, 320′ may have insufficient variety to fully characterize the nuisance contribution for all of these marks. By way of a specific example, there may be only two Zernikes modeled at step 325, 325′ (e.g., Z2,2 and Z2,3), providing two functions. Taking into account that a third known function which relates these two Zernikes, this means that step 420 may only be able to simultaneously solve the inverse model for three of the marks.

Fortunately, it can be appreciated that it is very unlikely all four marks will significantly degrade simultaneously. As such, a mark assessment step 415 may be performed to determine which one or more marks should be solved for at step 420. The mark assessment 415 may be based on a respective mark quality metric 410 for each mark. Presently, the measurement side (alignment sensor) already determines a suitable mark quality metric 410 in the form of a multiple correlation coefficient MCC. The mark quality metric may be monitored for each mark, and when one (or more) passes a threshold, the remainder of the method may be performed to determine the on product impact 440 and/or modeled true mark measurement data 450. Of course, if a more comprehensive model aberration model is used at step 325, 325′, then it may be possible to simultaneously solve the inverse model for all of the marks and reference to a mark quality metric may not be required.

This method may optionally comprise an additional validation step, where the on product impact 440 may be validated by comparing it to first measured (e.g., and modeled) overlay or parameter of interest data (e.g., as measured by a scatterometer). To make a proper comparison with the on product impact 440, the overlay impact contribution attributable to fiducial degradation should be isolated from the overlay data. This can be done by taking second measured overlay or parameter of interest data immediately after a fiducial swap (e.g., when the fiducial is known to be good and not degraded) from the measured overlay data; e.g., the on product impact 440 may be validated against a difference of (e.g., modeled) overlay data before and after a fiducial swap. This removes the effect of other drifting scanner components from the overlay impact of interest.

It can be appreciated that the methods described by FIGS. 3 and 4 have respective advantages and disadvantages. The correlation metric is a simple but relatively rough way to identify whether there are any measurement side issues. It requires lower spatially frequent data, e.g., the modeled results from measurement and exposure sides may be used, and the correlation may be computed quickly. A key advantage of this method is in its ability to indicate plate health despite the degradation of multiple marks. A key limitation being its inability to quantify any on-product impact due to fiducial degradation. Also, if a situation arises where more than three marks degrade simultaneously on both chucks, this approach will not work. Also, in the rare case that both chucks degrade in a similar way (e.g., resulting in modeling impact in the same direction), the chuck-to-chuck value will give no impact. As such, these methods may be alternatives, or may be complementary. For example, the simpler method of FIG. 3 may be used first to identify whether there is an issue, with the method of FIG. 4 used to quantify the impact of the problem and/or correct the measurement data for this impact.

While the specific example relating to alignment and fiducial mark degradation is described, the method can be understood to be equally applicable to leveling, where fiducial coating degradation can lead to a drift measurable only on the measurement side. The principles are exactly the same.

The concepts herein are equally applicable to a single stage lithographic apparatus or scanner used in combination with a stand-alone alignment tool or alignment station, where the alignment station is the measurement side and the scanner is the exposure side. As such, a lithographic apparatus arrangement may comprise a dual stage lithographic apparatus or single stage lithographic apparatus with stand-alone alignment station.

While specific embodiments of the invention have been described above, it will be appreciated that the invention may be practiced otherwise than as described.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 1-100 nm), as well as particle beams, such as ion beams or electron beams.

The term “lens”, where the context allows, may refer to any one or combination of various types of optical components, including refractive, reflective, magnetic, electromagnetic and electrostatic optical components. Reflective components are likely to be used in an apparatus operating in the UV and/or EUV ranges.

The breadth and scope of the present invention should not be limited by any of the above-described exemplary embodiments, but should be defined only in accordance with the following claims and their equivalents.

1. A method of determining fiducial degradation on a lithographic apparatus, the method comprising:
obtaining first fiducial metrology data from a measurement side of the lithographic apparatus;
obtaining second fiducial metrology data from an exposure side of the lithographic apparatus;
determining, by a hardware computer system, a correlation metric describing a correlation between the first fiducial metrology data and the second fiducial metrology data; and
determining whether a fiducial has degraded from the correlation metric.

2. The method as claimed in claim 1, wherein the first fiducial metrology data comprises a description of a fiducial surface of the fiducial.

3. The method as claimed in claim 2, wherein the description of a fiducial surface of the fiducial comprises alignment sensor data describing a position of one or more measurement structures on the fiducial surface.

4. The method as claimed in claim 2, wherein the description of a fiducial surface of the fiducial comprises level sensor data describing a height over the fiducial surface.

5. The method as claimed in claim 1, wherein the second fiducial metrology data comprises wavefront data describing aberrations of a lens of the lithographic apparatus.

6. The method as claimed in claim 1, comprising:
determining a common rate of drift between the first fiducial metrology data and the second fiducial metrology data; and
determining a correction for control of the lithographic apparatus from the common rate of drift.

7. The method as claimed in claim 1, wherein the correlation metric comprises a spearman correlation.

8. A method of determining fiducial degradation on a lithographic apparatus, the method comprising:
obtaining a first set of second fiducial metrology data relating to a first substrate support of the lithographic apparatus, the second fiducial metrology data being obtained from an exposure side of the lithographic apparatus;
obtaining a second set of second fiducial metrology data relating to a second substrate support of the lithographic apparatus;
determining, by a hardware computer system, a difference of the first set of second fiducial metrology data and the second set of second fiducial metrology data; and
determining whether a fiducial has degraded on either one or both of the first substrate support and/or second substrate support from the difference.

9. The method as claimed in claim 8, further comprising:
obtaining first fiducial metrology data from a measurement side of the lithographic apparatus, and determining one or both of an on-product impact of fiducial degradation and/or corrected first fiducial metrology data, corrected for the impact of the fiducial degradation, from the first fiducial metrology data and the difference.

10. The method as claimed in claim 9, wherein the first fiducial metrology data comprises a description of a fiducial surface of the fiducial.

11. The method as claimed in claim 10, wherein the description of a fiducial surface of the fiducial comprises alignment sensor data describing a position of one or more measurement structures on the fiducial surface.

12. The method as claimed in claim 10, wherein the description of a fiducial surface of the fiducial comprises level sensor data describing a height over the fiducial surface.

13. The method as claimed in claim 9, further comprising validating the on-product impact of fiducial degradation and/or corrected first fiducial metrology data against first measured parameter of interest data corrected using second measured parameter of interest data obtained when the fiducial was known to be good.

14. The method as claimed in claim 1, performed to determine whether the fiducial has degraded; and once degradation is determined:
obtaining a first set of second fiducial metrology data relating to a first substrate support of the lithographic apparatus, the second fiducial metrology data being obtained from an exposure side of the lithographic apparatus;
obtaining a second set of second fiducial metrology data relating to a second substrate support of the lithographic apparatus;
determining a difference of the first set of second fiducial metrology data and the second set of second fiducial metrology data; and
determining one or both of an on-product impact of fiducial degradation and/or corrected first fiducial metrology data, corrected for the impact of the fiducial degradation, from the first fiducial metrology data and the difference.

15. A non-transitory computer-readable medium comprising stored program instructions configured to perform at least the method of claim 1, when run on a suitable apparatus.

16. A processing system comprising a processor and the non-transitory computer-readable medium of claim 15.

17. A lithographic apparatus comprising the processing system of claim 16.

18. The lithographic apparatus as claimed in claim 17, further comprising:
a measurement side configured to perform measurements on a substrate;
an exposure side configured to perform exposures on the substrate;
a patterning device support configured to support a patterning device;
projection optics configured to project a pattern onto the patterning device; and
at least one substrate support configured to support the substrate.

19. A non-transitory computer-readable medium comprising stored program instructions configured to perform at least the method of claim 8, when run on a suitable apparatus.

20. The computer-readable medium of claim 15, wherein the first fiducial metrology data comprises a description of a fiducial surface of the fiducial.
